(19) United States
(12) Patent Application Publication
(10) Pub. No.: US 2004/0158439 A1
(43) Pub. Date: Aug. 12, 2004

(54) Magnetic field and acceleration sensor and method for simultaneously detecting magnetism and acceleration

(76) Inventors: Kyoung Soo Kim, Suwon (KR); Seung Do An, Suwon (KR); Ji man Cho, Seoul (KR)

Correspondence Address: LOWE HAUPTMAN GOPSTEIN GILMAN & BERNER, LLP, Suite 310, 1700 Diagonal Road, Alexandria, VA, 22314, US

(21) Appl. No.: 10/610,757

(22) Filed: Jul. 2, 2003

(30) Foreign Application Priority Data
Dec. 10, 2002 (KR) 2002-78223

(51) Int. Cl. G01D 21/02; G01P 15/125; G01R 33/02

(52) U.S. Cl. 702/190; 73/495; 73/514.32; 324/260; 702/87; 702/104; 702/107; 702/141

(57) ABSTRACT

A method and a magnetic field and acceleration sensor for simultaneously sensing magnetism and acceleration are disclosed, the method comprising the steps of applying a current to first and second movable structures which are movable in a first direction, spaced from fixedly arranged first and second sensing electrodes, respectively, and arranged in a plane perpendicular to the first direction, applying magnetic field and/or acceleration signals to the first and second movable structures, detecting capacitance changes from the first and second sensing electrodes, the capacitance changes being caused by the distance change between the first and second movable structures and the first and second sensing electrodes, respectively, outputting a magnetic field signal by subtracting a signal detected from the second sensing electrode from a signal detected from the first sensing electrode, and outputting an acceleration signal by adding the signals detected from the first and second sensing electrodes.

### BACKGROUND OF THE INVENTION

1. Field of the Invention

The present invention relates to a sensor implemented by a structure of a micro-electro mechanical system (MEMS) device, and more particularly to a magnetic field and acceleration sensor capable of simultaneously detecting both magnetism and acceleration and being implemented by a movable structure of an MEMS device, and a method for simultaneously detecting both magnetism and acceleration.

2. Description of the Related Art

MEMS is defined as a technology combining very small sized mechanical components such as sensors, valves, gears, mirrors and actuators formed in a semiconductor chip and microcircuits, and generally has applications in magnetic field sensors and accelerometers typically contained in an air bag of an automotive vehicle.

Basically, an MEMS device is implemented by incorporating microcircuits in the semiconductor chip having micro-mechanical components such as a sensor and a mirror thereon.

Such MEMS devices have a wide range of applications such as navigation systems, air flow detecting sensors embedded in a flight wing for sensing air flow changes in response to a surface resistance of a flight wing, optical switching devices for aiding exchange of optical signals at 20 ns between separate optical signal paths, sensor actuating type air-conditioning systems, and sensors embedded in the base of buildings for changing material characteristics by sensing air pressure. Among them, a navigation system based on a global positioning system (GPS) is the most representative application of the MEMS device.

A navigation system realized based on the GPS generally requires an absolute direction sensor so as to instruct a navigating object to proceed in a proper direction even in the case that a signal from a satellite of the GPS can not reach the navigation system, or rotate a map in a way that a direction of the map complies with the moving direction of the navigating object. A two-axis magnetic field sensor has been used as the absolute direction sensor in the navigation system.

The navigation system further requires an inclination compensation sensor for compensating inclination of the navigating object and distortion of a display because, if the navigating object is inclined, the display residing in the navigation system for displaying the absolute direction is distorted.

A number of studies of such acceleration sensors and magnetic field sensors have been made.

FIG. 1 illustrates a prior art magnetic field sensor which is disclosed in U.S. Pat. No. 6,215,318 granted to Margin Schoefthaler et al. and titled “Micromechanical Magnetic Field Sensor”. Referring to FIG. 1, when a current i flows into a movable current conductor 12b extending in an X-direction on a silicon substrate 11 and magnetic field Bz is present in a Z-direction, Lorentz force arises according to the following equation 1.

F_{y}=i(\vec{I}ₓ\vec{B}_{z}) (1)

That is, Lorentz force F_{y} acting in a Y-direction arises by the magnetic field B_{z} and the current Ix, and the movable current conductor 12b is deflected in the Y-direction by a deflection Δ y. As a result, a variable electrode 12e coupled to the movable current conductor 12b is moved together with the movable current conductor 12b, thereby causing displacement of an MEMS structure in the Y-direction. Such displacement of the MEMS structure produces changes in capacitance between the variable electrode 12e and the fixed electrode 12d. Then, such capacitance changes are detected as a voltage by processing electrical signals from electrical connections 15, 16 connected to the fixed electrodes 12.

The conventional magnetic sensor described above is disadvantageous in that acceleration in the Y-direction causes interference in the deflection of the movable electrical conductors, resulting in errors in sensing magnetism. Further, according to the conventional magnetic sensor structure shown in FIG. 1, it is difficult to realize X-direction and Y-direction magnetic field sensors. That is, to realize X-direction and Y-direction magnetic field sensors, the exemplary MEMS structure shown in FIG. 1 should be in vertically provided.

FIG. 2 illustrates a prior art accelerometer that is disclosed in U.S. Pat. No. 5,610,335 granted to Shaw, Kevin A et al. and titled “Microelectromechanical lateral accelerometer”.

The accelerometer, or acceleration sensor, associated with FIG. 2 is produced within a cavity formed in a substrate 21 by an etching process. Conductive pads 22 are formed on two opposing sidewalls of the cavity and the conductive pads 22 on the same sidewall are connected by a corresponding spring 23. From the middle of each spring 23, each corresponding beam 24 extends inwardly into the cavity. Each beam 24 has a plurality of movable fingers 25, each being distanced from the others at regular intervals. Further, fixed plates 27 are formed on the other sidewalls of the cavity, and a plurality of stationary fingers 25 are connected to each fixed plate 27. Each of the stationary fingers 25 is spaced from the others at regular intervals and positioned between the respective movable fingers 24. The respective fixed plates 27 are connected to respective sensing signal output pads 28.

The conventional accelerometer shown in FIG. 2 operates in such a way that the spring 23 moves along arrowed directions by acceleration force and therefore a distance between the movable fingers 25 and the stationary fingers 26 changes. The change in the distance between the movable fingers 25 and the stationary fingers 26 produces a change in capacitance between the movable fingers 25 and the stationary fingers 26 and such capacitance change is determined by a measuring technique and indicated as a certain signal.

In the conventional accelerometer, acceleration in a desired direction (X or Y direction) may be detected by adjusting a direction of the accelerometer to comply with the desired direction. Accordingly, a bi-directional (X and Y directions) accelerometer which simultaneously measures accelerations in X and Y directions can be realized by employing two one direction accelerometers shown in FIG. 2, which are arranged in perpendicular to each other.

The accelerometer of FIG. 2 is further disadvantageous in that it is not able to detect acceleration in the Z-direction.

Further, since the magnetic field sensor of FIG. 1 and the accelerometer of FIG. 2 are formed in separate devices, the navigation system must employ two separate sensors. Thus, an assembly process of the navigation system becomes complex.

### SUMMARY OF THE INVENTION

Therefore, the present invention has been made in view of the above problems, and it is an object of the present invention to provide a magnetic field and acceleration sensor and a method for simultaneously sensing magnetism and acceleration, the sensor being implemented by an MEMS device.

It is another object of the present invention to provide a magnetic field and acceleration sensor and a method for simultaneously sensing magnetism and acceleration, which has high sensing reliability that is obtained by eliminating interference by an acceleration component in sensing a a magnetic field component.

It is further another object of the present invention to provide a magnetic field and acceleration sensor and a method for simultaneously sensing magnetism and acceleration, capable of detecting Z-direction acceleration.

In accordance with the present invention, the above and other objects can be accomplished by the provision of a method for simultaneously sensing magnetic field and acceleration, comprising the steps of applying current to first and second movable structures which are movable in a first direction, spaced from a fixedly arranged first and second sensing electrodes, respectively, and arranged in a plane which is perpendicular to the first direction, applying magnetic field and/or acceleration signals to the first and second movable structures, detecting capacitance changes from the first and second sensing electrodes, the capacitance changes being caused by the distance change between the first and second movable structures and the first and second sensing electrodes, respectively, outputting a magnetic field signal by subtracting a signal detected from the second sensing electrode from a signal detected from the first sensing electrode, and outputting an acceleration signal by adding the signals detected from the first and second sensing electrodes.

Preferably, the first and second movable structures are movable in a Z-direction and arranged in an X-Y plane, current flows in a +Y-direction and a −Y-direction in the first and second movable structures, respectively, and the acceleration and magnetic field are applied to the first and second movable structures in the Z-direction and in an X-direction, respectively.

In accordance with another aspect of the present invention, there is provided a magnetic field and acceleration sensor capable of simultaneously detecting magnetism and acceleration comprising first and second movable structures which are movable in a direction and arranged in parallel with each other, first and second sensing electrodes spaced from the first and second movable structures, respectively, by a predetermined distance and arranged fixedly, an input electrode which is connected to one end of the first movable electrode and receives a predetermined frequency of current, a ground electrode connected to one end of the second movable electrode, a common electrode connected to respective other ends of the first and second movable structures for transferring the current from the first movable electrode to the second movable electrode.

Preferably, each of the first and second movable structures includes a supporting section fixedly arranged at a predetermined position, a spring having restoring force and connected to the supporting section, and a mass moving in a direction by a force and connected to the spring.

Preferably, the certain force is an acceleration force applied in the same direction along which the first and second movable structures are movable and/or a Lorentz force which arises in a direction perpendicular to a current flowing direction and the direction along which the first and second movable structures are movable.

Preferably, the sensor includes an adder for adding detected signals from the first and second sensing electrodes, and a subtracter for subtracting the detected signal from the second sensing electrode from the detected signal from the first sensing electrode, wherein an output signal of the adder is an acceleration sensing signal and an output signal of the subtracter is a magnetic field sensing signal.

Preferably, the sensor includes an oscillator for applying current with a resonance frequency of the first and second movable structures to the input electrode, a fixed phase amplifier for amplifying a predetermined frequency signal generated from the oscillator, a first and second amplifiers for amplifying signals detected from the first and second sensing electrodes, first and second balancing circuits for adjusting the signals output from the first and second amplifiers to have the same magnitude of acceleration force, an adder for adding balanced signals output from the first and second balancing circuits, thereby producing an added signal, a subtracter for subtracting the balanced signals output from the first and second balancing circuits, thereby producing a subtracted signal, first and second mixers for eliminating oscillating frequency components from the added signal and the subtracted signal using oscillating frequency signals output from the fixed phase amplifier, thereby producing demodulated signals, first and second low-pass filters for filtering the demodulated signals output from the first and second mixers to pass only low frequency signals having a frequency which is lower than a predetermined frequency, and a gain and offset adjusting unit for adjusting signals output from the first and second low-pass filters in gain and offset.

Preferably, the first and second movable structures are movable in the Z-direction and the current flows in ±Y-directions, and output signals of the sensor are an X-direction magnetism signal and a Z-direction acceleration signal, respectively.

In accordance with still another aspect of the present invention, there is provided a five-axis magnetic field and acceleration sensor capable of simultaneously detecting magnetism and acceleration comprising a first magnetic field and acceleration sensor arranged in such a way that current flows in the Y-direction, a second magnetic field and acceleration sensor arranged in a way that current flows in the X-direction, a first acceleration sensor arranged so as to detect an X-direction acceleration, a second acceleration sensor arranged so as to detect Y-direction acceleration, a first signal processing unit for outputting a Z-direction acceleration signal and an X-direction magnetic field signal by adding and subtracting first and second detecting signals, respectively, output from the first magnetic field and acceleration sensors, a second signal processing unit for outputting a Y-direction magnetic field signal by subtracting first and second detecting signals output from the second magnetic field and acceleration sensor, a third signal processing unit for outputting an X-direction acceleration signal by processing a detected signal output from the first acceleration sensor, and a fourth signal processing unit for outputting a Y-direction acceleration signal by processing a detected signal output from the second acceleration sensor.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view of a magnetic field sensor in accordance with the prior art;

FIG. 2 is a plan view of an accelerometer in accordance with the prior art;

FIG. 3 is a perspective view of primary elements of a magnetic field and acceleration sensor for simultaneously detecting a magnetic field and acceleration, in accordance with one embodiment of the present invention;

FIG. 4 is a sectional view of the sensor taken along a line A-A′ in FIG. 3, for explaining the sensing operation of the sensor in accordance with the present invention;

FIG. 5 is a perspective view showing primary elements of the magnetic field and acceleration sensor of the present invention and its signal connection between the primary elements for explaining a method for simultaneously sensing a magnetic field signal and an acceleration signal in accordance with the present invention;

FIG. 6 is a circuitry of a sensor for simultaneously sensing magnetic field signal and acceleration signal in accordance with the present invention; and

FIGS. 7A to 7E are spectrum diagrams obtained at a plurality of output points of the sensor shown in FIG. 6;

FIG. 8 is a five-axis sensor in accordance with another embodiment of the present invention.

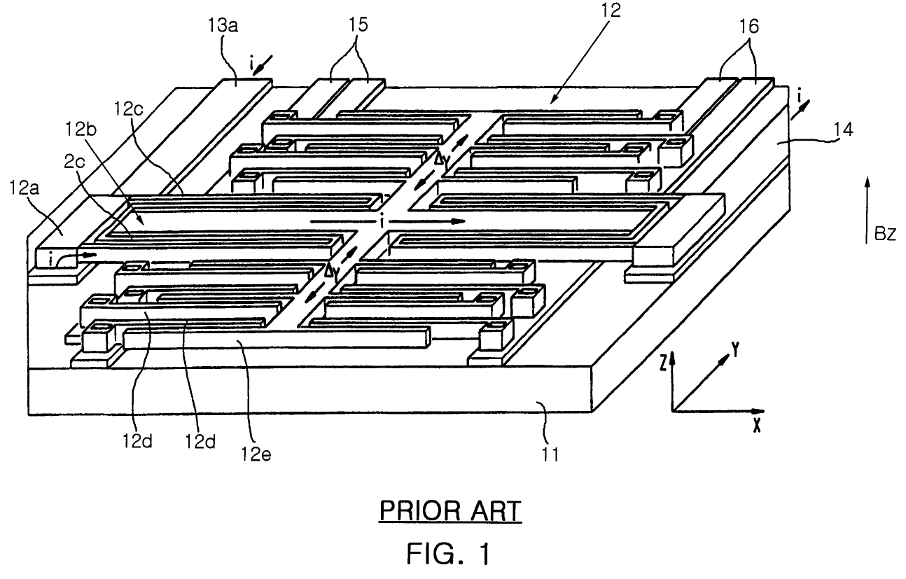

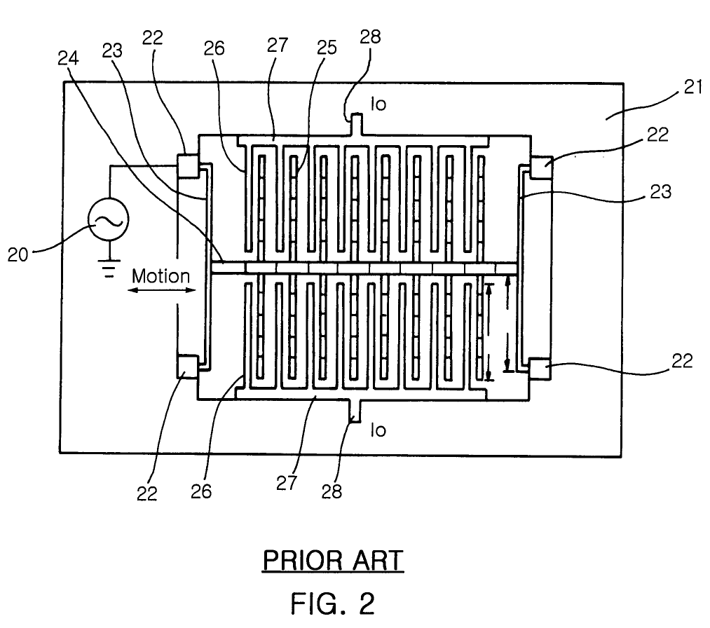

### DESCRIPTION OF THE PREFERRED EMBODIMENTS

A detailed description of a method for simultaneously sensing magnetism and acceleration, a magnetic field and acceleration sensor used for implementing the same method, and a five-axis sensor in accordance with preferred embodiments of the present invention will be given below with reference to the accompanying drawings.

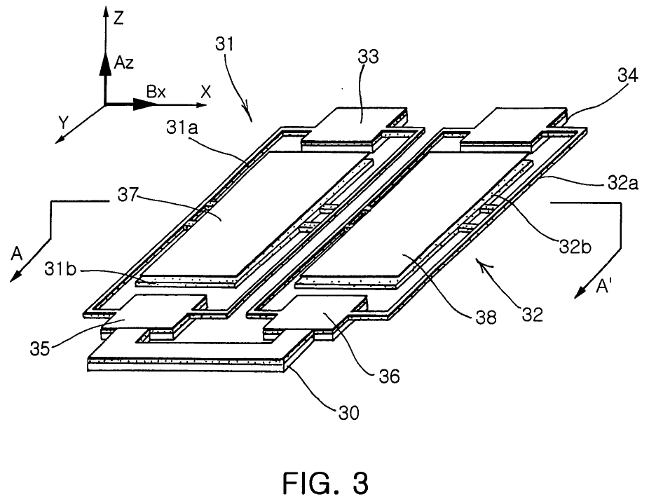

FIG. 3 illustrates primary elements of a magnetic field and acceleration sensor for simultaneously detecting magnetism and acceleration in accordance with one embodiment of the present invention. The magnetic field and acceleration sensor associated with FIG. 3 comprises first and second movable structures 31, 32 arranged in parallel with each other and being movable in a Z-direction by a certain force, and a plurality of electrodes making current flow into the first and second movable structures 31, 32 in opposite directions.

The first and second movable structures 31, 32 includes springs 31a, 32a, respectively, having restoring force, and masses 31b, 32b supported by the springs 31a, 32a, respectively and arranged in parallel with each other in an X-Y plane. The magnetic field and acceleration sensor further includes a supporting plate 30 positioned in the rear side (in the Y-direction) of the first and second movable structures 31, 32, and current path formed by a Cr/Au thin film deposited on the supporting plate 30 and the springs 31a, 32a connected to the supporting plate 30. An electrode 33 positioned in the front side (in the Y-direction) of the first movable structure 31 is connected to a signal source that applies current of a predetermined frequency, i.e. a resonance frequency of the movable structures. An electrode 34 positioned in the front side (in the Y-direction) of the second movable structure 32 is connected to a ground voltage. Electrodes 35 and 36 positioned in the rear side (in Y-direction) of the first and second movable structures 31, 32, respectively are connected to each other. Hereinafter, the electrodes 33 and 34 are called the input electrode and the ground electrode, respectively. The electrodes 35 and 36 are called common electrodes.

The magnetic field and acceleration sensor of the present invention further includes a first and second sensing electrodes 37, 38 spaced apart from the first and second mass plates 31b, 32b, respectively, in the Z-direction.

In the sensor of FIG. 3, when current of the resonance frequency of the movable structures 31, 32 is applied to the input electrode 33, the current flows from the input electrode 33 into the Cr/Au thin film (hereinafter called the upper electrode) on the spring 31a of the first movable structure 31 and travels to the common electrodes 35, 36 and an upper electrode on the spring 32a of the second movable structure 32, thereby finally reaching to the ground electrode 34.

Accordingly, the current flowing direction of the first movable structure 31 is opposite to the current flowing direction of the second movable structure 32.

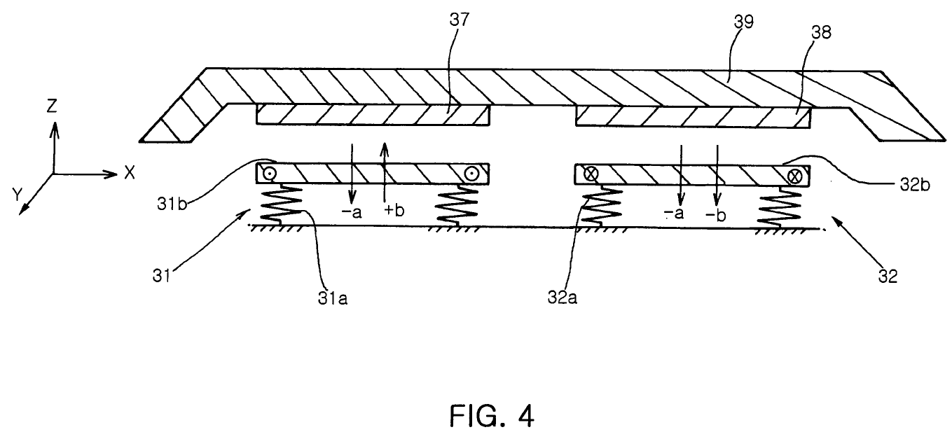

The operation of the sensor of FIG. 3 will be described below with reference to FIG. 4.

FIG. 4 is a schematic sectional view of the sensor shown in FIG. 3. Referring to FIG. 4, resonance frequency current outwardly flows in the mass 31b of the first movable structure 31, and inwardly flows in the mass 32b of the second movable structure 32.

In the structure of FIG. 4, when a magnetic field Bx is applied in the X-direction and an acceleration force Az is applied in the Z-direction, the first mass 31b is deflected by a deflection −a due to the acceleration force Az, and deflected by a deflection +b due to the Lorentz force caused by the magnetic field Bz and current Iy. Accordingly, total deflection of the first mass 31b by the magnetic field component and the acceleration component becomes −a+b.

As the same way, the second mass 32b is deflected by a deflection −a and −b due to the acceleration force Az and the magnetic field Bx, respectively. The second mass 32b is deflected in the opposite direction to the first mass 31b because the resonance current flows in the first mass 31b and the second mass 32b in opposite directions to each other. Accordingly, the total deflection of the second mass 32b becomes −a−b.

Accordingly, in the case of adding deflections of the first and second masses 31b and 32b, the total deflection becomes (−a+b)+(−a−b)=−2a, a deflection value caused by only the acceleration component. On the other hand, in the case of subtracting deflections of the first and second masses 31b and 32b, the total deflection becomes (−a+b)−(−a−b)=2b, a deflection value caused by only the magnetic field component.

The deflections of the first and second masses 31b and 32b change distances between the first and second masses 31b and 32b and the first and second sensing electrodes 37 and 38, respectively, thereby causing a change of capacitance there between. Then, a signal corresponding to a capacitance between the first electrode 37 and the first mass plate 31b is detected from the first electrode 37 and a signal corresponding to a capacitance between the second electrode 38 and the second mass plate 32b is detected from the second electrode 38. Accordingly, the magnitude of acceleration and the magnetic field can be determined by adding or subtracting the signals detected from the first and second sensing electrodes 37 and 38.

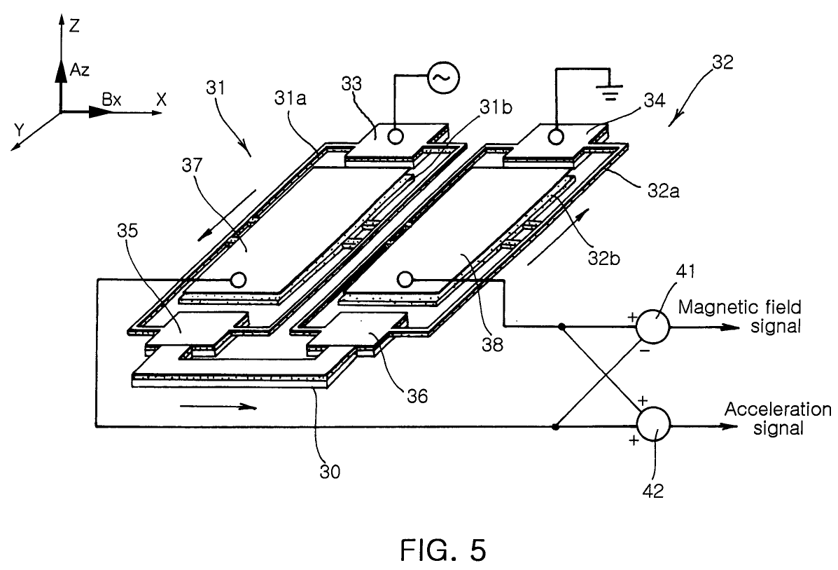

FIG. 5 illustrates primary elements of a magnetic field and acceleration sensor of the present invention, which is implemented based on the principal above. The magnetic field and acceleration sensor associated with FIG. 5 includes all the elements shown in FIG. 3 and additional elements such as a subtracter 41 for performing subtraction of the signals from the first and second electrodes 37, 38 and an adder 42 for performing addition of the signals from the first and second electrodes 37, 38. Further, the input electrode 33 is connected to an oscillator OSC generating a signal having a resonance frequency of a movable structure, and the ground electrode 34 is connected to a ground voltage.

Assuming that a magnetic field signal is applied in the X-direction, a force arises in the +Z direction in the first movable structure 31 and in the −Z direction in the second movable structure 32 by Fleming's left hand law which determines a direction of force which arises when magnetic field is applied to a conductor through which current flows. Further, magnitude of the force is determined by the equation 1 above. At this time, given that the deflection caused by the force is “b”, the first movable structure 31 is deflected by +b and the second movable structure 32 is deflected by −b by the electrical field in the X-direction.

Further, when an acceleration force is applied in the Z-direction, the first movable structure 31 and the second movable structure 32 are deflected to the opposite direction by the acceleration force. Given that the deflection caused by the acceleration is “a”, the first and second movable structures 31 and 32 are deflected by −a.

Accordingly, the total deflection of the first movable structure 31 becomes −a+b and the total deflection of the second movable structure 32 becomes −a−b.

The subtracter 41 subtracts the signals detected from the sensing electrodes 37, 38, thereby obtaining only magnetic field signals by eliminating the acceleration signals applied to the first and second movable structure 31 and 32 in the same direction. In the subtracting process, acceleration components are completely eliminated.

Further, the adder 42 adds the signal detected from the sensing electrodes 37, 38, thereby obtaining only the acceleration signals by eliminating magnetic field signals applied to the first and second movable structures 31 and 32 in opposite directions.

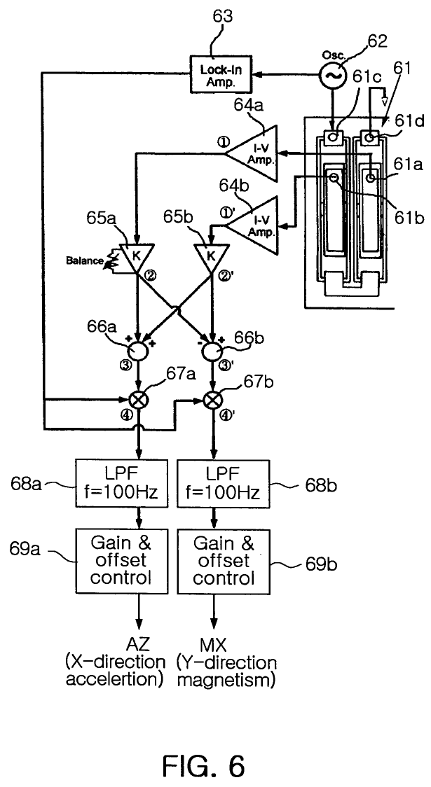

If the subtracter 41 or the adder 42 is omitted from the sensor shown in FIG. 5, the sensor without the subtracter 41 or the adder 42 may be operated as an acceleration sensor (accelerometer) or a magnetic field sensor. FIG. 6 illustrates a circuitry for testing performance of the magnetic field and acceleration sensor shown in FIG. 5.

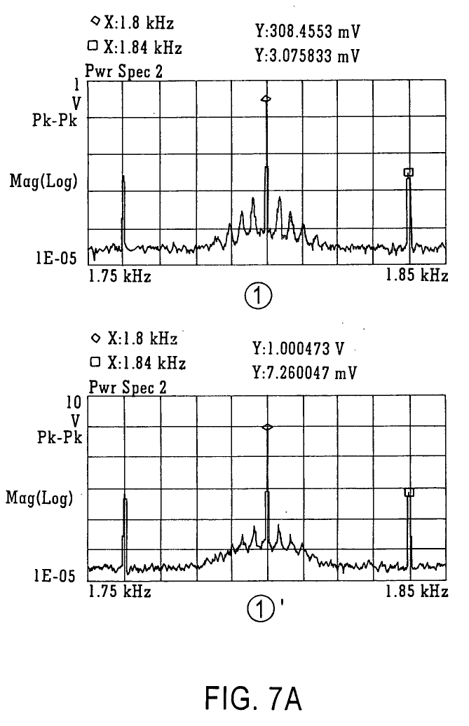

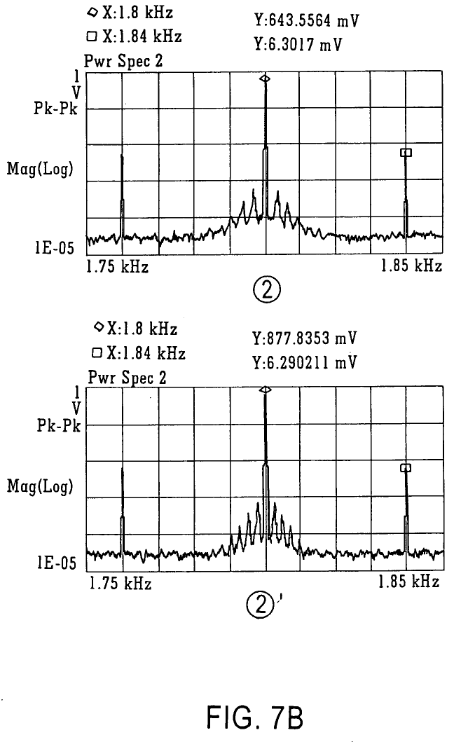

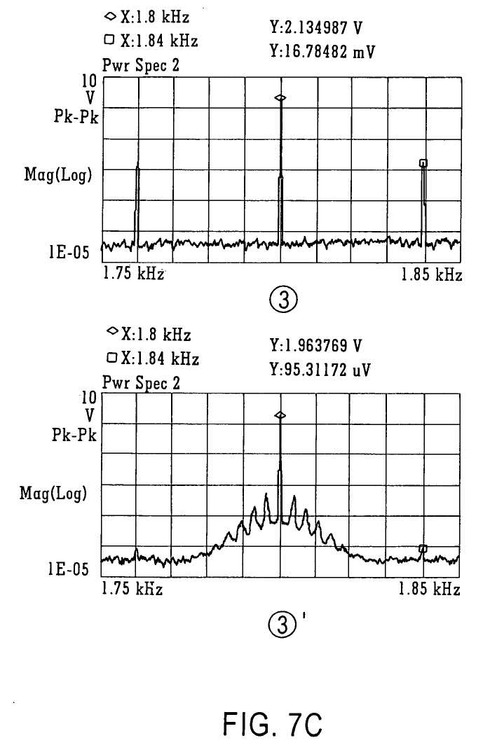

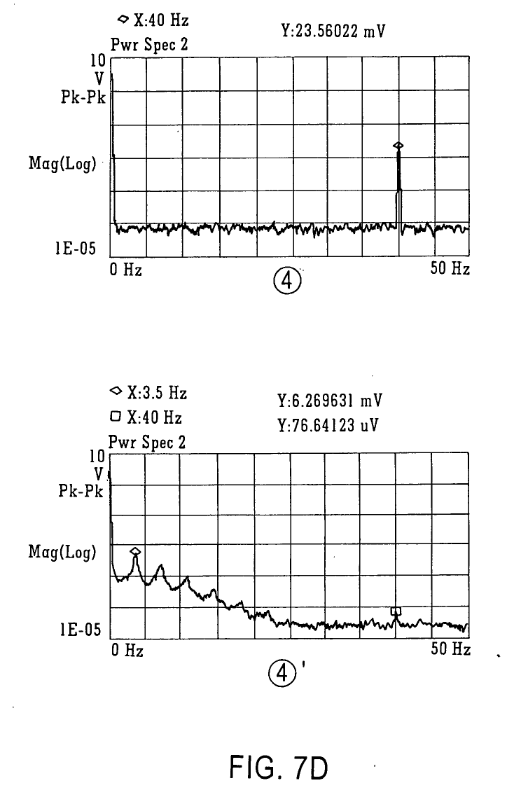

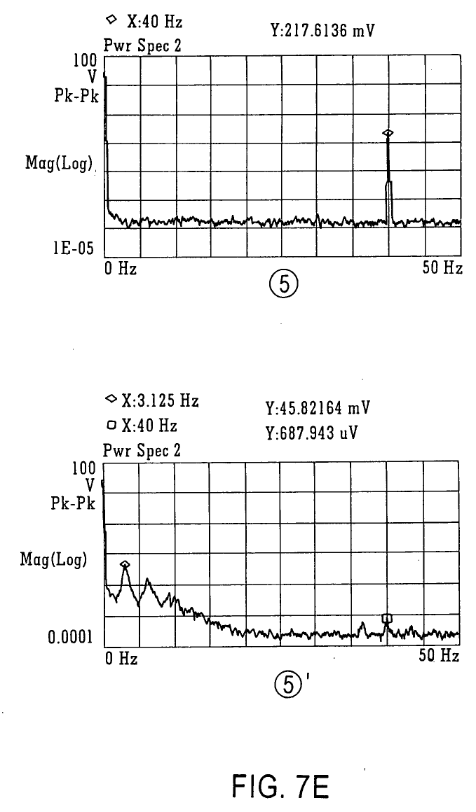

FIGS. 7A to 7E illustrate signals detected from a plurality of stages in the circuitry of FIG. 6.

Assuming that the circuitry of FIG. 6 operates under conditions that resonance frequency of a microstructure is 1.84 kHz, a magnitude of acceleration is about 40 Hz and a magnitude of a magnetic field is about 3 Hz.

The initial stage amplifiers 64a, 64b amplify signals from the first and second sensing electrodes 61a, 61b, respectively, to a pre-determined level. The amplified signals are illustrated in FIG. 7A.

In FIG. 7A, \mathring{1} denotes a signal which is detected from the first sensing electrode 61a at the right side and amplified by the initial stage amplifier 64a, and \mathring{1}′ denotes a signal which is detected from the second sensing electrode 61b at the left side and amplified by the initial stage amplifier 64b. The acceleration component and the magnetic field component are present in both signals \mathring{1}, \mathring{1}′, and phases of the signals \mathring{1} and \mathring{1}′ are opposite to each other.

Before performing subtraction and addition of the signals, the signals \mathring{1}, \mathring{1}′ are balanced by balancing circuits 65a, 65b, respectively, thereby producing balanced signals \mathring{2}, \mathring{2}′ so that the balanced signals \mathring{2}, \mathring{2}′ have the same magnitude of acceleration component. FIG. 7B illustrates the balanced signals \mathring{2}, \mathring{2}′ output from the balancing circuits 65a, 65b, respectively.

Next, the balanced signals \mathring{2}, \mathring{2}′ are added by the adder 66a, thereby producing an added signal \mathring{3} and subtracted by the subtracter 66b, thereby producing a subtracted signal \mathring{3}′.

FIG. 7C illustrates the added signal \mathring{3} and the subtracted signal \mathring{3}′.

As described above, the added signal \mathring{3} has no magnetic field components because the magnetic field components of the balanced signals \mathring{2}, \mathring{2}′ are opposite to each other in phase and therefore eliminated by performing the addition. Therefore the added signal \mathring{3} has only acceleration components with the same phase. On the other hand, the subtracted signal \mathring{3}′ has no acceleration components because the acceleration components are eliminated due to being opposite in phase and thus has only magnetic field components in the same phase.

Next, since both of the added signal \mathring{3} and the subtracted signal \mathring{3}′ include the resonance frequency current components applied by the oscillator 62, it is necessary to eliminate the resonance frequency current components from the added signal \mathring{3} and the subtracted signal \mathring{3}′. The added signal \mathring{3} and the subtracted signal \mathring{3}′ are mixed with oscillating frequency signals output from a fixed phase amplifier 63 so that the resonance frequency current components are eliminated from the signals \mathring{3} and \mathring{3}′, and a demodulated added signal \mathring{4} and a subtracted signal \mathring{4}′ are produced.

FIG. 7D illustrates the demodulated added signal \mathring{4} and the demodulated subtracted signal \mathring{4}′. The demodulated added signal \mathring{4} has a pure acceleration component of 40 Hz which is externally applied for testing. The demodulated subtracted signal \mathring{4} has a pure magnetic field component of 3 Hz which is externally applied for testing. That is, acceleration component is almost attenuated.

FIG. 7E illustrates output signals \mathring{5}, \mathring{5}′ obtained by filtering and adjusting the demodulated added signal \mathring{4} and demodulated subtracted signal \mathring{4}′, respectively, using a low-pass filter and a gain and offset unit.

The testing results illustrated in FIGS. 7A to 7E prove that the magnetic field and acceleration can be detected at the same time, and further that it is possible to offset and eliminate the acceleration component from the detected magnetic field signal.

Further, it is possible to realize a 5-axis magnetic field and acceleration sensor capable of detecting accelerations in X, Y and Z-directions and magnetic fields in X and Y-directions.

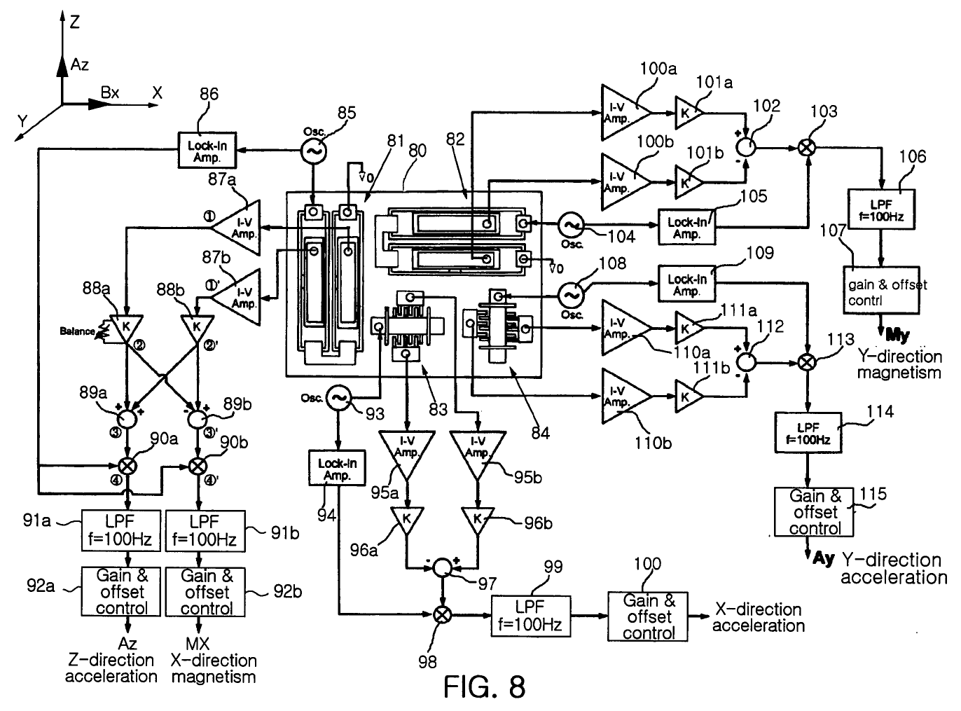

FIG. 8 illustrates a 5-axis magnetic field and acceleration sensor in accordance with the present invention.

Referring to FIG. 8, the 5-axis acceleration and magnetic field sensor includes first and second magnetic field and acceleration sensors 81, 82 which are arranged in the Y-direction and the X-direction, respectively, and further includes a first and second acceleration sensors 83, 84 arranged in the X-direction and the Y-direction, respectively. All the sensors 81, 82, 83 and 84 are formed on the same substrate.

A predetermined frequency of resonance current generated by an oscillator 85 is applied to an input electrode of the first magnetic field and acceleration sensor 81, and at the same time an output signal of the oscillator 85 is input to the fixed phase amplifier 86 and then amplified.

Then, signals output from two sensing electrodes of the sensor 81 are amplified by amplifiers 87a, 87b, respectively, and then balanced by balancing circuit 88a, 88b so that the amplified signals have the same magnitude of acceleration components. The balanced signals are input to an adder 89a and a subtracter 89b, so that an added signal and subtracted signal are produced. The added signal and the subtracted signal are mixed with oscillating frequency signals in mixers 90a, 90b, respectively, so as to be demodulated. The demodulated added signal and subtracted signal are input to low-pass filters 91a, 91b, respectively and then gain and offset adjusting units 92a, 92b, respectively, so that the demodulated signals are filtered and adjusted in gain and offset. The signals output from the gain and offset adjusting units 92a, 92b are a Z-direction acceleration signal Az and an X-direction magnetic field signal Mx, respectively.

Further, a predetermined frequency signal generated by an oscillator 104 is input to the sensor 82 arranged in the X-axis. Two signals detected by two sensing electrodes of the sensor 82 are amplified by amplifiers 100a, 10b, respectively, and then balanced by balancing circuits 101a, 101b, respectively. A balanced signal is subtracted from the other balanced signal by a subtracter, so that a subtracted signal is produced. The subtracted signal is mixed with oscillating frequency signal in a mixer 103 so as to be demodulated. Then, the demodulated signal is filtered by a low-pass filter 106 and then input to a gain and offset adjusting unit 107. An output signal output from the gain and offset adjusting unit 107 is a Y-direction magnetic field signal My.

Here, the Z-direction acceleration signal Az that can be obtained by adding the signals from the sensing electrodes of the sensor 82 is the same as the Z-direction acceleration signal Az obtained by the sensor 81. Accordingly, it is not necessary to obtain the Z-direction acceleration signal from the sensor 82. Only the Y-direction magnetic field signal My is detected by the sensor 82.

For detecting an X-direction acceleration signal and a Y-direction acceleration signal, a predetermined frequency current generated by oscillators 93 and 108 is applied to input electrodes of the first and second acceleration sensors 83, 84, respectively, and then signals are detected by sensing electrodes of the sensors 83 and 84 and amplified. The amplified signals are balanced by balancing circuits (96a, 96b), (111a, 111b) and then subtracted by subtracters 98 and 113, respectively. The subtracted signals are demodulated by mixers 98, 113, respectively, and passed through row-pass filters 99, 114 and gain and offset adjusting units 100, 115, sequentially. Signals output from the gain and offset adjusting units 100, 115 are an X-direction acceleration signal Ax and a Y-direction acceleration signal Ay, respectively.

The first and second magnetic field and acceleration sensors 81, 82 are sensors capable of detecting both a magnetic field component and n acceleration component at the same time. The sensors 81 and 82 may be the magnetic field and acceleration sensor shown in FIG. 3. However, the first and second acceleration sensors 83, 84 may be known conventional accelerometers.

As described above, the magnetic field and acceleration sensor of the present invention is advantageous in that it is possible to detect both magnetic field component and acceleration component at the same time.

The magnetic field and acceleration sensor of the present invention is advantageous that it has improved sensing reliability because it is possible to eliminate interference by an acceleration component while detecting a magnetic field signal.

Further, in the case that the magnetic field and acceleration sensor of the present invention is employed in a navigation system, since the magnetic field sensor and the acceleration sensor is formed in a single sensor, a total size of the navigation system is reduced and an assembly process of the navigation system is simplified.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for simultaneously sensing a magnetic field and acceleration, comprising the steps of:
applying a current to first and second movable structures which are movable in a first direction, spaced from fixedly arranged first and second sensing electrodes, respectively, and arranged in a plane which is perpendicular to the first direction;
applying a magnetism and/or an acceleration to the first and second movable structures;
detecting capacitance changes from the first and second sensing electrodes, the capacitance changes being caused by the distance change between the first and second movable structures and the first and second sensing electrodes, respectively;
outputting a magnetic field signal by subtracting a signal detected from the second sensing electrode from a signal detected from the first sensing electrode; and
outputting an acceleration signal by adding the signals detected from the first and second sensing electrodes.

2. The method according to claim 1, wherein the first and second movable structures are movable in a Z-direction and arranged in an X-Y plane, current flows in a +Y-direction and a −Y-direction in the first and second movable structures, respectively, and the acceleration and magnetic field are applied to the first and second movable structures in the Z-direction and in the X-direction, respectively.

3. A magnetic field and acceleration sensor capable of simultaneously detecting magnetism and acceleration comprising:
first and second movable structures which are movable in a direction and arranged in parallel with each other;
first and second sensing electrodes spaced from the first and second movable structures, respectively, by a predetermined distance and arranged fixedly;
an input electrode which is connected to one end of the first movable electrode and receives a predetermined frequency of current;
a ground electrode connected to one end of the second movable electrode; and
a common electrode connected to respective other ends of the first and second movable structures for transferring the current from the first movable electrode to the second movable electrode.

4. The magnetic field and acceleration sensor according to claim 3, wherein each of the first and second movable structures includes a supporting section fixedly arranged at a predetermined position, a spring having restoring force and connected to the supporting section, and a mass moving in a direction by a force and connected to the spring.

5. The magnetic field and acceleration sensor according to claim 3, wherein the certain force is an acceleration force which is applied in the same direction along which the first and second movable structures are movable and/or a Lorentz force which arises in a direction perpendicular to a current flowing direction and the direction along which the first and second movable structures are movable.

6. The magnetic field and acceleration sensor according to claim 3, wherein the sensor includes:
an adder for adding detected signals from the first and second sensing electrodes; and
a subtracter for subtracting the detected signal from the second sensing electrode from the detected signal from the first sensing electrode,
wherein an output signal of the adder is an acceleration sensing signal and an output signal of the subtracter is a magnetic field sensing signal.

7. The magnetic field and acceleration sensor according to claim 3, wherein the sensor includes:
an oscillator for applying current with a resonance frequency of the first and second movable structures to the input electrode;
a fixed phase amplifier for amplifying a predetermined frequency signal generated from the oscillator;
first and second amplifiers for amplifying signals detected from the first and second sensing electrodes;
first and second balancing circuits for adjusting the acceleration force of the signals output from the first and second amplifiers to have the same magnitude;
an adder for adding balanced signals output from the first and second balancing circuits, thereby producing an added signal;
a subtracter for subtracting the balanced signals output from the first and second balancing circuits, thereby producing a subtracted signal;
first and second mixers for eliminating oscillating frequency components from the added signal and the subtracted signal using oscillating frequency signals output from the fixed phase amplifier, thereby producing demodulated signals;
first and second low-pass filters for filtering the demodulated signals output from the first and second mixers to pass only low frequency signals having a frequency which is lower than a predetermined frequency;
a gain and offset adjusting unit for adjusting signals output from the first and second low-pass filters in gain and offset.

8. The magnetic field and acceleration sensor according to claim 7, wherein when the first and second movable structures are movable in a Z-direction, the current flows in ±Y-directions, and output signals of the sensor are an X-direction magnetism signal and a Z-direction acceleration signal, respectively.

9. A five-axis magnetic field and acceleration sensor capable of simultaneously detecting magnetism and acceleration comprising:
a first magnetic field and acceleration sensor arranged in a such way that current flows in a Y-direction;
a second magnetic field and acceleration sensor arranged in a such way that current flows in an X-direction;
a first acceleration sensor arranged so as to detect an X-direction acceleration;
a second acceleration sensor arranged so as to detect a Y-direction acceleration;
a first signal processing unit for outputting a Z-direction acceleration signal and an X-direction magnetic field signal by adding and subtracting first and second detecting signals, respectively, output from the first magnetic field and acceleration sensor;
a second signal processing unit for outputting a Y-direction magnetic field signal by subtracting first and second detecting signals output from the second magnetic field and acceleration sensor;
a third signal processing unit for outputting an X-direction acceleration signal by processing a detected signal output from the first acceleration sensor; and
a fourth signal processing unit for outputting a Y-direction acceleration signal by processing a detected signal output from the second acceleration sensor.
